(19) United States
(12) Patent Application Publication
(10) Pub. No.: US 2024/0172570 A1
(43) Pub. Date: May 23, 2024

(54) SEMICONDUCTOR DEVICE AND METHOD FOR FABRICATING THE SAME

(71) Applicant: SK hynix Inc., Icheon-si (KR)

(72) Inventor: Jeong Hwan SONG, Icheon-si (KR)

(21) Appl. No.: 18/448,287

(22) Filed: Aug. 11, 2023

(30) Foreign Application Priority Data
Nov. 21, 2022 (KR) 10-2022-0156528

(51) Int. Cl. H10N 70/20; H10B 63/00; H10N 70/00

(52) U.S. Cl. CPC H10N 70/25; H10B 63/80; H10N 70/043; H10N 70/063; H10N 70/883; H10N 70/826; H10N 70/8265

(57) ABSTRACT

Semiconductor devices and methods for fabricating the semiconductor devices are disclosed. In some implementations, a semiconductor device includes first and second conductive layers spaced apart from each other, and a memory cell interposed between the first and second conductive layers. The memory cell includes a first selector layer, a second selector layer spaced apart from the first selector layer, and an insulating layer interposed between the first selector layer and the second selector layer.

### PRIORITY CLAIM AND CROSS-REFERENCE TO RELATED APPLICATION

This patent document claims the priority and benefits of Korean Patent Application No. 10-2022-0156528, filed on Nov. 21, 2022, which is incorporated herein by reference in its entirety.

### TECHNICAL FIELD

This patent document relates to a semiconductor technology.

### BACKGROUND

The recent trend toward miniaturization, low power consumption, high performance, and multi-functionality in the electrical and electronics industry has compelled the semiconductor manufacturers to focus on, high-performance, high capacity semiconductor devices. Examples of such high-performance, high-capacity semiconductor devices include memory devices that can store data by switching between different resistance states according to an applied voltage or current, such as an RRAM (resistive random access memory), a PRAM (phase change random access memory), an FRAM (ferroelectric random access memory), an MRAM (magnetic random access memory), an E-fuse (electronic fuse).

### SUMMARY

In some embodiments of the disclosed technology, a semiconductor device may include: first and second conductive layers spaced apart from each other; and a memory cell interposed between the first and second conductive layers, wherein the memory cell includes: a first selector layer: a second selector layer spaced apart from the first selector layer; and an insulating layer interposed between the first selector layer and the second selector layer. In some embodiments of the disclosed technology, a method for fabricating a semiconductor device may include forming an insulating material layer between a first conductive layer and a second conductive layer, forming a first selector layer arranged adjacent to the first conductive layer by doping a first dopant into a lower portion of the insulating material layer adjacent to the first conductive layer, forming a second selector layer arranged adjacent to the second conductive layer by doping a second dopant into an upper portion of the insulating material layer adjacent to the second conductive layer, wherein a portion of the insulating material layer between the first selector layer and the second selector layer is not doped with the first and second dopants.

### BRIEF DESCRIPTION OF THE DRAWINGS

FIG. 1 is a perspective view illustrating a semiconductor device based on some embodiments of the disclosed technology.

FIG. 2 is a cross-sectional view illustrating the memory cell of FIG. 1 in more detail.

FIG. 3A illustrates an operation of the memory cell of FIG. 2.

FIG. 3B illustrates another example of the state of (a) of FIG. 3A.

FIG. 4 illustrates formation of a conductive path and consequent generation of Joule's heat.

FIG. 5A is a current-voltage graph showing the write operation of FIG. 3A.

FIG. 5B is a current-voltage graph showing the erase operation of FIG. 3A.

FIG. 6 is a current-voltage graph showing a read operation of the memory cell of FIG. 2.

FIG. 7 is a cross-sectional view illustrating a memory cell based on some embodiments of the disclosed technology.

FIGS. 8A to 8D are cross-sectional views illustrating a method for manufacturing a memory cell based on some embodiments of the disclosed technology.

FIG. 9 is a cross-sectional view showing a memory cell according to another embodiment of the present disclosure. Detailed descriptions of substantially the same parts as those of the foregoing embodiments will be omitted.

FIGS. 10A and 10B are cross-sectional views illustrating an example of a method of forming the memory cell of FIG. 9.

FIGS. 11A to 11C are cross-sectional views illustrating another example of a method of forming the memory cell of FIG. 9.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

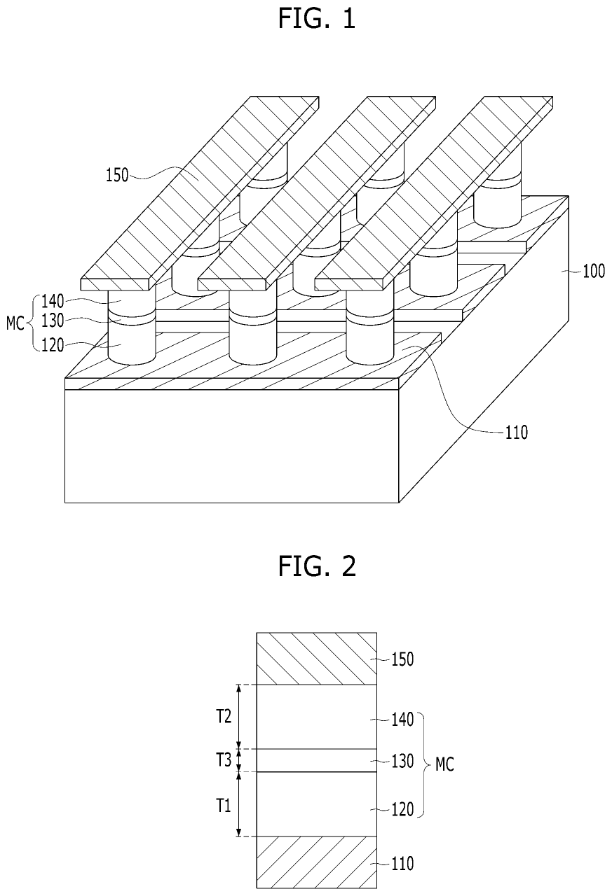

FIG. 1 is a perspective view illustrating a semiconductor device based on some embodiments of the disclosed technology.

Referring to FIG. 1, a semiconductor device based on some embodiments of the disclosed technology may include a substrate 100, a plurality of first conductive lines 110 disposed over the substrate 100 and extending parallel to each other in a first direction, a plurality of second conductive lines 150 disposed over the plurality of first conductive lines 110 to be spaced apart from the plurality of first conductive lines 110 in a vertical direction and extending (e.g., the second conductive lines 150 may be arranged parallel to each other) in a second direction crossing the first direction, and a plurality of memory cells MC disposed between the first conductive lines 110 and the second conductive lines 150 at intersection regions wherein the first conductive lines 110 vertically overlap the second conductive lines 150. The first direction and the second direction may be horizontal directions parallel to an upper surface of the substrate 100.

The substrate 100 may include a semiconductor material such as silicon. In addition, the substrate 100 may include a certain lower structure (not shown). For example, the substrate 100 may include a driving circuit electrically connected to the first conductive lines 110 and/or the second conductive lines 150 to activate the first conductive lines 110 and/or the second conductive lines 150 and/or control operations associated with the first conductive line 110 and/or the second conductive line 150.

The memory cell MC may have a pillar shape that is spaced apart from an adjacent memory cell MC. In some embodiments of the disclosed technology, the memory cell MC may have a circular pillar shape or a shape similar thereto. However, the disclosed technology is not limited thereto, and the shape of the memory cell MC may be variously modified. In another example, the memory cell MC may have a rectangular pillar shape that has sidewalls aligned with sidewalls of the second conductive line 150 in the first direction and sidewalls aligned with sidewalls of the first conductive line 110 in the second direction.

The memory cell MC may include a stacked structure that includes a first selector layer 120, an insulating layer 130, and a second selector layer 140 that are stacked on top of one another, and may function as a self-selecting memory, which functions as both a memory element and a selector, as will be discussed below.

The memory cell MC may have a variable resistance characteristic for storing different data values by switching between different resistance states according to a voltage applied through both ends (e.g., upper end and lower end) thereof, that is, the first conductive line 110 and the second conductive line 150. In addition, the memory cell MC may have a threshold switching characteristic, and thus no or very little current flows when the voltage applied to both ends of the memory cell MC is less than a predetermined threshold voltage, current flows (e.g., the current flow increases rapidly) when the applied voltage exceeds the threshold voltage. The memory cell MC may be turned on or off based on the threshold voltage.

In some implementations, the threshold voltage of the memory cell MC may depend on the resistance state of the memory cell MC. That is, the memory cell MC may have different threshold voltages according to different resistance states. For example, when the memory cell MC is in a first resistance state, it may have a first threshold voltage, and when the memory cell MC is in a second resistance state different from the first resistance state, it may have a second threshold voltage different from the first threshold voltage. Thus, the memory cell MC may function as a self-selecting memory that functions as a memory element as well as a selector.

As a result, while data is being written to each of the plurality of memory cells MC, current leakage that may occur between memory cells MC sharing the first conductive line 110 or the second conductive line 150 may be prevented or reduced.

In some embodiments of the disclosed technology, since the memory cell MC simultaneously functions as a memory element and a selector, the memory cell MC may perform its memory operations without requiring additional memory elements or selectors, thereby simplifying the manufacturing process. In addition, since it is easy to implement a semiconductor device having a cross-point structure including the memory cell MC, and thus it is possible to highly integrate the semiconductor device.

In some embodiments of the disclosed technology, the memory cell MC including the first selector layer 120, the insulating layer 130, and the second selector layer 140, and the operation of the memory cell MC may include the following structures.

FIG. 2 is a cross-sectional view illustrating the memory cell of FIG. 1 in more detail.

Referring to FIG. 2, the memory cell MC may be interposed between the first conductive line 110 and the second conductive line 150, and may include the first selector layer 120, the insulating layer 130, and the second selector Layer 140.

Each of the first conductive line 110 and the second conductive line 150 may include various conductive materials, for example, a metal such as platinum (Pt), tungsten (W), aluminum (Al), copper (Cu), tantalum (Ta), and titanium (Ti), a metal nitride such as titanium nitride (TiN) and tantalum nitride (TaN), or a combination thereof, and may have a single layer structure or a multilayer structure. In another embodiment, instead of the first conductive line 110 and the second conductive line 150, conductive layers having various shapes may be connected to both ends of the memory cell MC, respectively.

The first selector layer 120 may be disposed relatively adjacent or closer to the first conductive line 110 compared to the second selector layer 140, and the second selector layer 140 may be disposed relatively adjacent or closer to the second conductive line 150 compared to the first selector layer 120. The insulating layer 130 may be disposed between the first selector layer 120 and the second selector layer 140. Although not shown, the memory cell MC may further include an electrode material disposed between the first conductive line 110 and the first selector layer 120 and/or between the second conductive line 150 and the second selector layer 140. The electrode material may include various conductive materials, for example, a metal such as platinum (Pt), tungsten (W), aluminum (Al), copper (Cu), tantalum (Ta), and titanium (Ti), a metal nitride such as titanium nitride (TiN) and tantalum nitride (TaN), or a combination thereof. Alternatively, the electrode material may include carbon.

The first selector layer 120 may have a threshold switching characteristic. In some

implementations, no or very slight current flows when the applied voltage is less than a predetermined threshold voltage, whereas current flows (e.g., the current flow increases rapidly) when the applied voltage exceeds the threshold voltage. Accordingly, the first selector layer 120 may be turned on or off depending on whether the applied voltage exceeds the threshold voltage. In one example, the first selector layer 120 may be turned on at a threshold voltage or higher. The threshold voltage of the first selector layer 120 will be hereinafter referred to as a first sub-threshold voltage (Sub-Vth1). The first selector layer 120 may include a diode, an ovonic threshold switching (OTS) material such as a chalcogenide-based material, a mixed ionic electronic conducting (MIEC) material such as a metal-containing chalcogenide-based material, a metal insulator transition (MIT) material such as NbO₂ and VO₂, or others. Alternatively, as will be discussed below with reference to FIG. 7, the first selector layer 120 may have a structure including an insulating material layer and a dopant doped in the insulating material layer.

The second selector layer 140 may have a threshold switching characteristic. In some implementations, no or very slight current flows when the applied voltage is less than a predetermined threshold voltage, whereas current flows e.g., the current flow increases rapidly) when the applied voltage exceeds the threshold voltage. Accordingly, the second selector layer 140 may be turned on or off depending on whether the applied voltage exceeds the threshold voltage. In one example, the second selector layer 140 may be turned on at a threshold voltage or higher. The threshold voltage of the second selector layer 140 will be hereinafter referred to as a second sub-threshold voltage (Sub-Vth2). The second selector layer 140 may include a diode, an ovonic threshold switching (OTS) material such as a chalcogenide-based material, a mixed ionic electronic conducting (MIEC) material such as a metal-containing chalcogenide-based material, a metal insulator transition (MIT) material such as NbO₂ and VO₂, or others. Alternatively, as will be discussed below with reference to FIG. 7, the second selector layer 140 may have a structure including an insulating material layer and a dopant doped in the insulating material layer.

In one example, the first selector layer 120 and the second selector layer 140 may be formed of the same material. In another example, the first selector layer 120 and the second selector layer 140 may be formed of different materials from one another. Also, a thickness T1 of the first selector layer 120 and a thickness T2 of the second selector layer 140 may be the same as or similar to each other. For example, the thickness T1 of the first selector layer 120 may have a value ranging from 90% to 110% of the thickness T2 of the second selector layer 140 because, as will be described later in FIG. 4, when a conductive path is formed by a current flow through a certain layer, Joule's heat generated in the middle region of the conductive path is the largest, as will be discussed below.

The insulating layer 130 may include various insulating materials. For example, the insulating layer 130 may include a silicon-containing insulating material such as silicon oxide, silicon nitride, or silicon oxynitride, an insulating metal oxide, an insulating metal nitride, or a combination thereof. The insulating layer 130 may have an insulating property, but when an applied voltage is greater than a predetermined value, a conductive path may be formed in the insulating layer 130 by a soft breakdown to allow current to flow. To this end, the insulating layer 130 may have a thin thickness of several to several tens of nm. A thickness T3 of the insulating layer 130 may be smaller than the thickness T1 of the first selector layer 120 and the thickness T2 of the second selector layer 140. A voltage that causes the soft breakdown of the insulating layer 130 will be referred to as a breakdown voltage Vbd hereinafter.

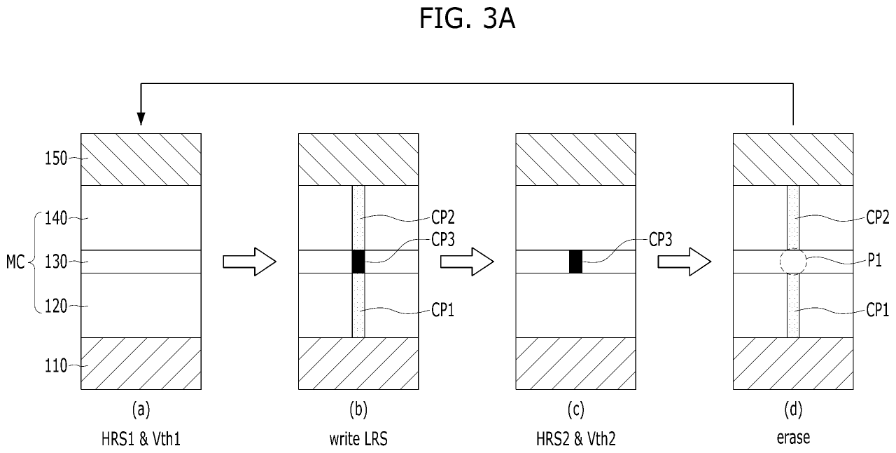

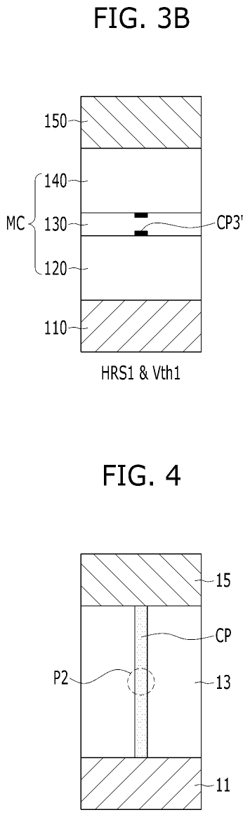

FIG. 3A illustrates an operation of the memory cell of FIG. 2.

Referring to (a) of FIG. 3A, no conductive path is formed in the first selector layer 120, the insulating layer 130, and the second selector layer 140 of the memory cell MC.

This state may be referred to as a first high resistance state HRS1. The first high resistance state HRS1 may correspond to an initial state immediately after the memory cell MC is fabricated or a state after an erase operation of (d) of FIG. 3A, which will be discussed below. When no voltage is applied to the first conductive line 110 and the second conductive line 150, the first high resistance state HRS1 may be maintained.

The threshold voltage in the first high resistance state HRS1 will be hereinafter referred to as the first threshold voltage Vth1. The first threshold voltage Vth1 may have a value corresponding to the sum of the first sub-threshold voltage Sub-Vth1 of the first selector layer 120, the breakdown voltage Vbd of the insulating layer 130, and the second sub-threshold voltage Sub-Vth2 the second selector layer 140.

Referring to (b) of FIG. 3A, a write operation may be performed by applying a write voltage to the first conductive line 110 and the second conductive line 150. The write operation may refer to an operation for changing the first high resistance state HRS1 to a low resistance state LRS. The write voltage may have a value greater than the first threshold voltage Vth1, that is, the sum of the first sub-threshold voltage Sub-Vth1, the breakdown voltage Vbd, and the second sub-threshold voltage Sub-Vth2.

When the write voltage is applied, the first selector layer 120 may be turned on to form a first conductive path CP1 in the first selector layer 120, the second selector layer 140 may be turned on to form a second conductive path CP2 in the second selector layer 140, and the soft breakdown of the insulating layer 130 may occur to form a third conductive path CP3 in the insulating layer 130. Accordingly, between the first conductive line 110 and the second conductive line 150, a current flow by the first conductive path CP1, the third conductive path CP3, and the second conductive path CP2 may be created. As a result, the memory cell MC may have the low resistance state LRS.

Referring to (c) of FIG. 3A, when the write voltage applied to the first conductive line 110 and the second conductive line 150 is removed, the first selector layer 120 and the second selector layer 140 may be turned off, and the first conductive path CP1 and the second conductive path CP2 may disappear. On the other hand, since the third conductive path CP3 in the insulating layer 130 is created due to the soft breakdown and has a non-volatile characteristic, it may be maintained even if the write voltage is removed. In some implementations, the non-volatile characteristic may include a memory characteristic that can retain stored information even after power is removed. This state may be referred to as a second high resistance state HRS2. Since a current flow in the memory cell MC is not actually allowed in the second high resistance state HRS2, the second high resistance state HRS2 may have a higher resistance than the low resistance state LRS. However, since the third conductive path CP3 exist in the insulating layer 130, the second high resistance state HRS2 may have a lower resistance than the first high resistance state HRS1. When no voltage is applied to the first conductive line 110 and the second conductive line 150, the second high resistance state HRS2 may be maintained.

The threshold voltage in the second high resistance state HRS2 will be hereinafter referred to as the second threshold voltage Vth2. The second threshold voltage Vth2 may have a value corresponding to the sum of the first sub-threshold voltage Sub-Vth1 of the first selector layer 120 and the second sub-threshold voltage Sub-Vth2 of the second selector layer 140.

Referring to (d) of FIG. 3A, the erase operation may be performed by applying an erase voltage to the first conductive line 110 and the second conductive line 150. The erase operation may refer to an operation for changing the second high resistance state HRS2 of the memory cell MC to the first high resistance state HRS1. The erase voltage may have a value greater than the second threshold voltage Vth2, that is, the sum of the first sub-threshold voltage Sub-Vth1 and the second sub-threshold voltage Sub-Vth2. Furthermore, the erase voltage may have a smaller magnitude than the first threshold voltage Vth1. This is because, if the erase voltage has a magnitude greater than or equal to the first threshold voltage Vth1, a conductive path is formed again in the insulating layer 130 due to the soft breakdown. In addition, the polarity of the erase voltage may be the same as that of the write voltage. For example, when a relatively positive voltage is applied to the second conductive line 150 compared to the first conductive line 110 during the write operation, a relatively positive voltage may be applied to the second conductive line 150 compared to the first conductive line 110 during the erase operation. The reverse case may also be possible.

When the erase voltage is applied, the first selector layer 120 may be turned on to form the first conductive path CP1 in the first selector layer 120 again, and the second selector layer 140 may be turned on to form the second conductive path CP2 in the second selector layer 140 again. On the other hand, the third conductive path CP3 in the insulating layer 130 may be eliminated by Joule's heat (see P1). For reference, when forming a conductive path penetrating a certain layer, Joule's heat may be the largest in a middle region of the conductive path. This is exemplarily shown in FIG. 4.

FIG. 4 illustrates formation of a conductive path and consequent generation of Joule's heat.

Referring to FIG. 4, a layer 13 that allows current to flow according to an applied voltage may be interposed between a first conductive layer 11 and a second conductive layer 15. The layer 13 may be, for example, a selector layer. When a conductive path CP connecting the first conductive layer 11 and the second conductive layer 15 is formed in the layer 13, the magnitude of Joule's heat generated in the middle region P2 of the conductive path CP may be the largest.

Returning to (d) of FIG. 3A, since the insulating layer 130 is interposed between the first selector layer 120 and the second selector layer 140 having the same or similar thickness, the insulating layer 130 may located in the middle of the memory cell MC including the first selector layer 120, the insulating layer 130, and the second selector layer 140. Therefore, when a conductive path penetrating the memory cell MC is formed, that is, before the third conductive path CP3 of the insulating layer 130 disappears at the beginning of the erase operation, the first conductive path CP1 and the second conductive path CP2 may be connected to the third conductive path CP3 to form current flowing through the memory cell MC, and thus, Joule's heat may be greatest in the insulating layer 130. As a result, the third conductive path CP3 in the insulating layer 130 may be easily eliminated.

When the erase voltage is removed, the state of (a) of FIG. 3A may occur again. That is, the first selector layer 120 and the second selector layer 140 may be turned off, and the first conductive path CP1 and the second conductive path CP2 may disappear. As a result, the memory cell MC may have the first high resistance state HRS1 in which the conductive paths of the first selector layer 120, the insulating layer 130, and the second selector layer 140 are all eliminated.

Although FIG. 3A shows a case where the third conductive path CP3 of the insulating layer 130 completely disappears after the erase operation, part of the third conductive path CP3 may remain as will be discussed with reference to FIG. 3B.

FIG. 3B illustrates another example of the state of (a) of FIG. 3A.

Referring to FIG. 3B, after the erase operation, a third conductive path CP3′ (e.g., part of the third conductive path CP3) of the insulating layer 130 may remain. Even in this case, since the third conductive path CP′ does not pass through the insulating layer 130 to connect the first selector layer 120 and the second selector layer 140, the memory cell MC may have the first high resistance state HRS1 and the first threshold voltage Vth1.

In some implementations, immediately after the fabrication of the memory cell MC or after the erase operation, the memory cell MC may have the first high resistance state HRS1 and the first threshold voltage Vth1. Then, during the write operation, the memory cell MC may be changed to the low resistance state LRS. After the write operation, the memory cell MC may have the second high resistance state HRS2 and the second threshold voltage Vth2. The write voltage may have a magnitude greater than the first threshold voltage Vth1, and the erase voltage may have a magnitude greater than the second threshold voltage Vth2 and smaller than the first threshold voltage Vth1 while having the same polarity as the write voltage.

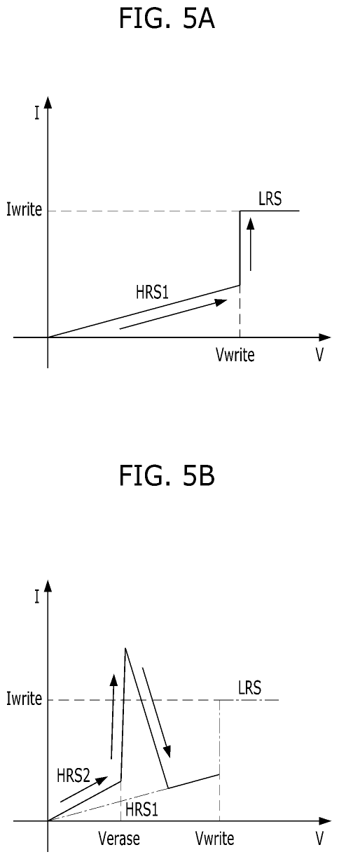

FIG. 5A is a current-voltage graph showing the write operation of FIG. 3A, and FIG. 5B is a current-voltage graph showing the erase operation of FIG. 3A.

Referring to FIGS. 3A and 5A, when a write voltage Vwrite greater than the first threshold voltage Vth1 is applied to the memory cell MC in the first high resistance state HRS1, the first to third conductive paths CP1, CP2, and CP3 penetrating the first selector layer 120, the insulating layer 130, and the second selector layer 140 may be formed, and thus, a rapidly increasing current flow may be generated. The current above may be referred to as a write current Iwrite, and the memory cell MC may have the low resistance state LRS.

Referring to FIGS. 3A and 5B, when an erase voltage Verase greater than the second threshold voltage Vth2 and less than the first threshold voltage Vth1 is applied to the memory cell MC in the second high resistance state HRS2, the conductive paths CP1 and CP2 may be formed in the first selector layer 120 and the second selector layer 140 and connected to the conductive path CP3 previously formed in the insulating layer 130, and thus, a rapidly increasing current flow may be generated. When the erase voltage Verase is larger than the second threshold voltage Vth2 by a predetermined amount, a current greater than the write current Iwrite may flow instantaneously through the first to third conductive paths CP1, CP2, and CP3, thereby generating a large amount of Joule's heat in the insulating layer 130 positioned in the middle of the memory cell MC, and thus, the conductive path CP3 of the insulating layer 130 may be eliminated or destroyed. As a result, the current flow may be cut off, and the memory cell MC may change to the first high resistance state HRS1 again.

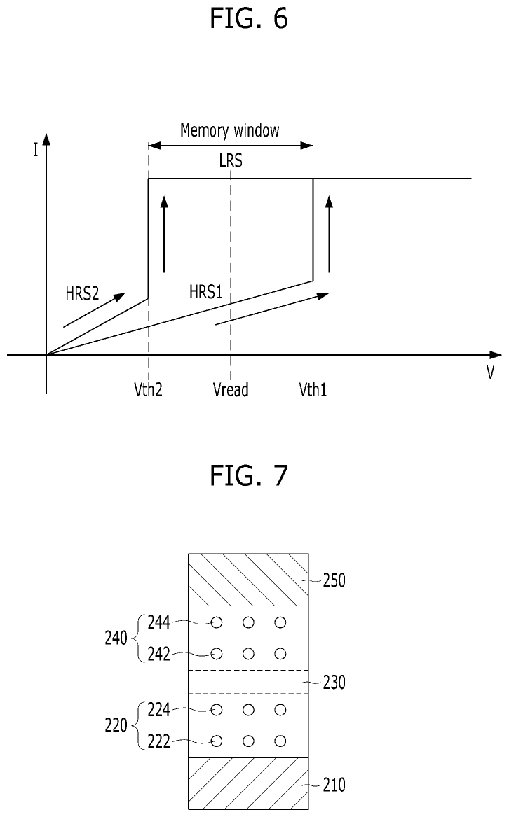

FIG. 6 is a current-voltage graph showing a read operation of the memory cell of FIG. 2.

Referring to FIGS. 2, 3A and 6, when the memory cell MC is not operated, the memory cell MC may have the first high resistance state HRS1 and the first threshold voltage Vth1 or the second high resistance state HRS2 and the second threshold voltage Vth2. The resistance of the first high resistance state HRS1 may be greater than that of the second high resistance state HRS2, and the first threshold voltage Vth1 may be greater than the second threshold voltage Vth2.

When the voltage applied to the memory cell MC in the first high resistance state HRS1 reaches the first threshold voltage Vth1, the first and second conductive paths CP1 and CP2 may be formed in the first selector layer 120 and the second selector layer 140 of the memory cell MC, and the third conductive path CP3 may be formed in the insulating layer 130. As a result, the memory cell MC may have the low resistance state LRS.

When the voltage applied to the memory cell MC in the second high resistance state HRS2 reaches the second threshold voltage Vth2, the first and second conductive paths CP1 and CP2 may be formed in the first selector layer 120 and the second selector layer 140 of the memory cell MC, and may be connected to the third conductive path CP3 of the insulating layer 130. As a result, the memory cell MC may have the low resistance state LRS.

A read voltage Vread applied during the read operation may have the same polarity as the write voltage and the erase voltage, and may have a magnitude between the first threshold voltage Vthl and the second threshold voltage Vth2. When the read voltage Vread is applied, the memory cell MC in the first high resistance state HRS1 may maintain its state, allowing only a small current to flow therethrough, but the memory cell MC in the second high resistance state HRS2 may be changed to the low resistance state LRS, allowing a large current to flow therethrough. By sensing this current flow, the resistance state of the memory cell MC, that is, data stored in the memory cell MC may be read.

Here, the read voltage Vread may have a smaller magnitude than the erase voltage Verase. In other words, the read current flowing through the memory cell MC in the second high resistance state HRS2 may be smaller than the erase current. If the read voltage Vread and the read current is equal to or exceeds the erase voltage Verase and the erase current, the third conductive path CP3 of the insulating layer 130 may be removed by Joule's heat and the resistance state of the memory cell MC may be changed to the first high resistance state HRS1, and thus the read operation may not be performed.

The disclosed technology can be implemented in some embodiments to provide a semiconductor device that includes a memory cell having a self-selecting memory characteristic by including an insulating layer interposed between two selector layers may perform memory operations such as read and write operations without requiring additional memory elements and/or separate selectors. Accordingly, the semiconductor device can be manufactured more simply at a reduced cost.

In addition, the disclosed technology can be implemented in some embodiments to highly integrate a semiconductor device having a cross-point structure including such a memory cell.

In addition, memory operations of the memory cell can be performed using a voltage having only one polarity, the driving voltage may be reduced compared to using voltages having two polarities.

Furthermore, as will be described below, when the memory cell is implemented by doping dopants at different ion implantation depths into an insulating material layer, manufacturing processes may be further simplified, and cost may be further reduced accordingly.

FIG. 7 is a cross-sectional view illustrating a memory cell based on some embodiments of the disclosed technology.

Referring to FIG. 7, a memory cell implemented based on some embodiments may include a first selector layer 220, an insulating layer 230, and a second selector 240 that are interposed between a first conductive layer 210 and a second conductive layer 250.

The first conductive layer 210 and the second conductive layer 250 may respectively correspond to the first conductive line 110 and the second conductive line 150 of FIG. 2 described above.

The first selector layer 220 may include a first insulating material layer 222 and a first dopant 224 doped into the first insulating material layer 222 by ion implantation or others.

The first insulating material layer 222 may include a silicon-containing insulating material such as silicon oxide, silicon nitride, and silicon oxynitride, an insulating metal oxide, an insulating metal nitride, or a combination thereof. The insulating metal oxide may include, for example, aluminum oxide, zirconium oxide, hafnium oxide, tungsten oxide, titanium oxide, nickel oxide, copper oxide, manganese oxide, tantalum oxide, niobium oxide, or iron oxide. The insulating metal nitride may include, for example, aluminum nitride. Deep traps capable of trapping conductive carriers, for example, electrons, may exist in the insulating material layer 222. An energy level of the deep traps may be similar to an energy level of a valence band of the first insulating material layer 222.

The first dopant 224 may include an element that does not move within the first insulating material layer 222 and is able to generate shallow traps providing a passage for the movement of the conductive carriers, for example, electrons in the first insulating material layer 222. An energy level of the shallow traps generated by the first dopant 224 may be greater than the energy level of the deep traps of the first insulating material layer 222, and may be less than an energy level of a conduction band of the first insulating material layer 222. To generate such a shallow trap, various elements different from constituent elements of the first insulating material layer 222 may be used as the first dopant 224. The element used as the first dopant 224 may generate an energy level capable of accommodating the conductive carriers in the first insulating material layer 222. When the first insulating material layer 222 contains silicon, the first dopant 224 may include a metal having a different valence from silicon. For example, when the first insulating material layer 222 includes silicon oxide or silicon nitride, the first dopant 224 may include at least one of aluminum (Al), lanthanum (La), niobium (Nb), vanadium (V), tantalum (Ta), tungsten (W), chromium (Cr), molybdenum (Mo), boron (B), nitrogen (N), carbon (C), phosphorus (P), and arsenic (As). Alternatively, when the first insulating material layer 222 contains a metal, the first dopant 224 may include a metal having a different valence from the metal or silicon. For example, when the first insulating material layer 222 includes aluminum oxide or aluminum nitride, the first dopant 224 may include at least one of titanium (Ti), copper (Cu), zirconium (Zr), hafnium (Hf), niobium (Nb), vanadium (V), tantalum (Ta), tungsten (W), chromium (Cr), molybdenum (Mo), boron (B), nitrogen (N), carbon (C), phosphorus (P), and arsenic (As).

When a voltage higher than a threshold voltage is applied to the first selector layer 220, the conductive carriers trapped in the deep traps may jump to the shallow traps by thermal emission or tunneling. As the conductive carriers move through the shallow traps, an “on” state in which current flows through the first selector layer 220 may be implemented. On the other hand, when the voltage applied to the first selector layer 220 drops below the threshold voltage, the number of the conductive carriers moving from the deep traps to the shallow traps may decrease, thereby suppressing the movement of the conductive carriers through the shallow traps. Accordingly, an “off” state in which substantially no (or very slight) current flows may be formed. As a result, a threshold switching characteristic of the first selector layer 220 may be obtained.

Similarly, the second selector layer 240 may include the second insulating material layer 242 and the second dopant 244 doped into the second insulating material layer 242 by ion implantation or others. Since the types of the second insulating material layer 242 and the second dopant 244, and the operation method of the second selector layer 240 are substantially the same as those described with respect to the first selector layer 220, the detailed description thereof will be omitted. The second insulating material layer 242 may be formed of the same material as or a different material from the first insulating material layer 222. The second dopant 244 may be the same as or different from the first dopant 224.

The insulating layer 230 may include a silicon-containing insulating material such as silicon oxide, silicon nitride, and silicon oxynitride, an insulating metal oxide, an insulating metal nitride, or a combination thereof. The insulating layer 230 may be formed of the same material as at least one of the first insulating material layer 222 and the second insulating material layer 242, or may be formed of a different material from the first insulating material layer 222 and the second insulating material layer 242.

As will be discussed below, the first selector layer 220, the insulating layer 230, and the second selector layer 240 may be formed by doping dopants at different depths into a single insulating material. In this case, the first insulating material layer 222, the insulating layer 230, and the second insulating material layer 242 may be formed of the same insulating material. For example, the first selector layer 220, the insulating layer 230, and the second selector layer 240 may be formed of silicon dioxide.

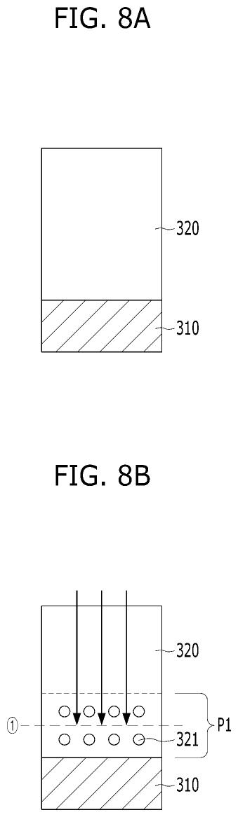

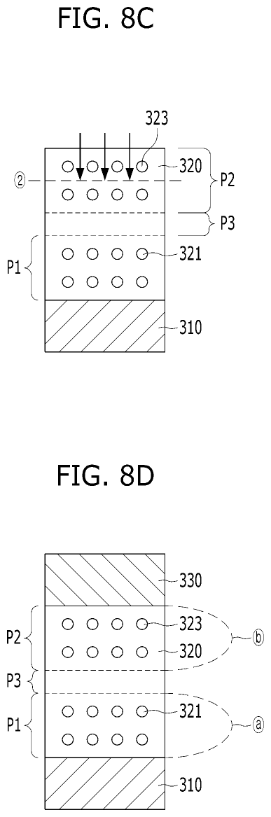

FIGS. 8A to 8D are cross-sectional views illustrating a method for manufacturing a memory cell based on some embodiments of the disclosed technology.

Referring to FIG. 8A, an insulating material layer 320 may be formed over a conductive layer 310.

The insulating material layer 320 may include a silicon-containing insulating material such as silicon oxide, silicon nitride, and silicon oxynitride, an insulating metal oxide, an insulating metal nitride, or a combination thereof. The insulating material layer 320 may be formed by various deposition methods such as chemical vapor deposition (CVD) and atomic layer deposition (ALD).

Referring to FIG. 8B, a first selector layer PI may be formed by doping a first dopant 321 into a lower portion of the insulating material layer 320.

The first dopant 321 may include an element capable of generating shallow traps providing a passage for the movement of conductive carriers, for example, electrons in the insulating material layer 320. When the insulating material layer 320 contains silicon, the first dopant 321 may include a metal having a different valence from silicon. When the insulating material layer 320 contains a metal, the first dopant 321 may include a metal having a valence different from that of the metal or silicon. Also, doping of the first dopant 321 may be performed by ion implantation. Here, doping may be performed so that Rp(projected range) point (\textcircled{1} in FIG. 8B) is located in the first selector layer P1 in the vertical direction, for example, in the middle of the first selector layer P1 during ion implantation. Rp point may mean a target depth for ion implantation.

Referring to FIG. 8C, a second selector layer P2 may be formed by doping a second dopant 323 into an upper portion of the insulating material layer 320.

The second dopant 323 may include an element capable of generating shallow traps providing a passage for the movement of conductive carriers, for example, electrons in the insulating material layer 320. When the insulating material layer 320 contains silicon, the second dopant 323 may include a metal having a different valence from silicon. When the insulating material layer 320 contains a metal, the second dopant 323 may include a metal having a valence different from that of the metal or silicon. Also, doping of the second dopant 323 may be performed by ion implantation. Here, doping may be performed so that the Rp point (\textcircled{2} in FIG. 8C) is located in the second selector layer P2 in the vertical direction, for example, in the middle of the second selector layer P2 during ion implantation. The second dopant 323 may be the same as or different from the first dopant 321.

Since dopants are not doped in an area P3 between the lower and upper portions of the insulating material layer 320, that is, between the first selector layer P1 and the second selector layer P2, the insulating material layer 320 may remain as it is.

The first selector layer P1, the second selector layer P2, and the dopant-free remaining portion P3 of the insulating material layer 320 may correspond to the first selector layer 120, the second selector layer 140, and the insulating layer 130 of FIG. 2, respectively. Accordingly, the first selector layerP1 and the second selector layer P2 may have identical or similar thicknesses to each other. The remaining portion P3 may have a thickness smaller than the thickness of the first selector layer P1 and the thickness of the second selector layer P2. For example, the remaining portion P3 may have a thickness of several to several tens of nm.

Referring to FIG. 8D, a second conductive layer 330 may be formed over the second selector layer P2, and thus, a memory cell may be formed.

The concentration of the first dopant 321 in the first selector layer P1 may be highest at the center and may decrease toward the upper and lower surfaces (see dotted line \textcircled{a} in FIG. 8D).

In addition, the concentration of the second dopant 323 in the second selector layer P2 may be highest at the center and may decrease toward the upper and lower surfaces (see dotted line \textcircled{b} in FIG. 8D).

Meanwhile, in the above embodiments, when a memory cell is in an on state, the location or number of conductive paths formed in the memory cell may be random. In this case, the threshold voltage distribution of a first selector layer and/or a second selector layer may increase according to the location or number of the conductive paths. When the threshold voltage distribution of the first selector layer and/or the second selector layer increases, Joule heat efficiency may decrease and operating characteristics of the memory cell may deteriorate. Hereinafter, embodiments in which the location or number of the conductive paths can be more easily controlled by limiting an area where the conductive paths are formed in the memory cell will be proposed.

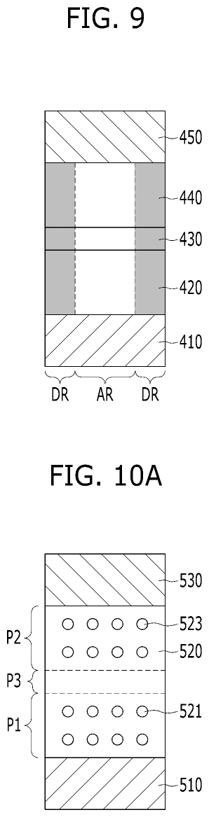

FIG. 9 is a cross-sectional view showing a memory cell according to another embodiment of the present disclosure. Detailed descriptions of substantially the same parts as those of the foregoing embodiments will be omitted.

Referring to FIG. 9, the memory cell of the present embodiment may include a memory cell including a first selector layer 420, an insulating layer 430, and a second selector 440. The memory cell may be interposed between a first conductive layer 410 and a second conductive layer 450.

Here, an edge region, corresponding to a predetermined width from the sidewall of the memory cell, may correspond to a dead region DR in which the first and second selector layers 420 and 440 do not perform a function as a selector, that is, a function that is turned on or off according to an applied voltage. Accordingly, a central region surrounded by the edge region of the memory cell may correspond to an active region AR in which the first and second selector layers 420 and 440 function as a selector.

In the case where a selector layer includes an insulating material doped with dopants as described above, if the concentration of the dopants becomes low enough to make it difficult to form sufficient trap sites or the dopant disappears, the selector layer may lose its function as a selector. When the active region AR of the first selector layer 420 includes a first insulating material layer and a first dopant doped into the first insulating material layer by ion implantation or the like, the dead region DR of first selector layer 420 may include the first insulating material layer including the first dopant at a concentration lower than that of the active region AR of the first selector layer 420, or the dead region DR of first selector layer 420 may include the first insulating material layer that does not include the first dopant. For example, when the active region AR of the first selector layer 420 includes silicon oxide doped with arsenic (As) at a first concentration, the dead region DR of the first selector layer 420 may include silicon oxide doped with arsenic (As) at a second concentration lower than the first concentration, or undoped silicon oxide. Similarly, When the active region AR of the second selector layer 440 includes a second insulating material layer and a second dopant doped into the second insulating material layer by ion implantation or the like, the dead region DR of second selector layer 440 may include the second insulating material layer including the second dopant at a concentration lower than that of the active region AR of the second selector layer 440, or the dead region DR of second selector layer 440 may include the second insulating material layer that does not include the second dopant. For example, when the active region AR of the second selector layer 440 includes silicon oxide doped with arsenic (As) at a third concentration, the dead region DR of the second selector layer 440 may include silicon oxide doped with arsenic (As) at a fourth concentration lower than the third concentration, or undoped silicon oxide. The first concentration and the third concentration may be substantially equal to each other, and the second concentration and the fourth concentration may be substantially equal to each other.

In this case, the threshold voltage distribution of the first selector layer 420 and/or the second selector layer 440 may decrease because the conductive path is locally formed only in the active region AR. As a result, the efficiency of the Joule heat may be increased so that an operating current required during an erase operation may be reduced, and operating characteristics of the memory cell may be improved.

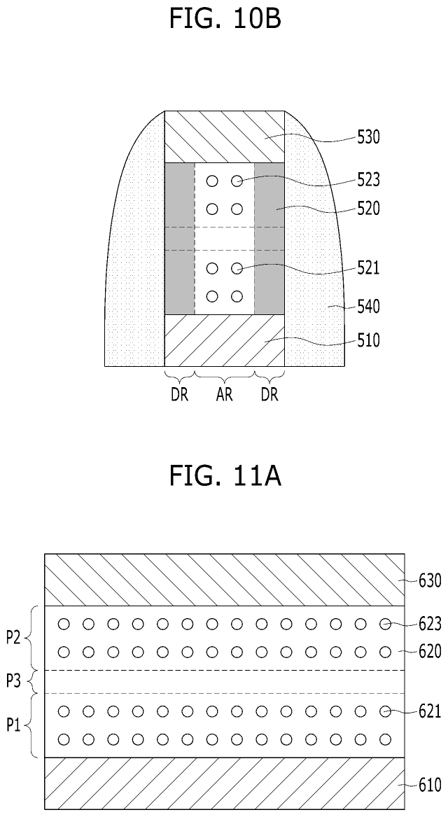

FIGS. 10A and 10B are cross-sectional views illustrating an example of a method of forming the memory cell of FIG. 9.

Referring to FIG. 10A, substantially the same processes as in FIGS. 8A to 8D may be performed to form a stacked structure including a conductive layer 510, a first selector layer Pl in which a first dopant 521 is doped in an insulating material layer 520, a second selector layer P2 in which a second dopant 523 is doped in the insulating material layer 520, and a portion P3 located between the first selector layer P1 and the second selector layer P2 and including the insulating material layer 520 not doped with a dopant, and a second conductive layer 530. This stacked structure may be in a state patterned into a pillar shape.

Referring to FIG. 10B, a spacer 540 may be formed over a sidewall of the stacked structure of FIG. 10A. The spacer 540 may include various insulating materials such as silicon nitride, silicon oxide, or a combination thereof, and may be formed using various deposition methods such as PVD (Physical Vapor Deposition), CVD (Chemical Vapor Deposition), ALD (Atomic Layer Deposition), or the like.

Here, when the spacer 540 is deposited, a precursor including an element capable of removing the first and second dopants 521 and 523 by reacting with the first and second dopants 521 and 523 may be used. When this element reacts with the first and second dopants 521 and 523, the first and second dopants 521 and 523 may be lost from the first and second selector layers P1 and P2. As an example, when the first and second dopants 521 and 523 include arsenic (As), the spacer 540 may be deposited using a chlorine-based When a chlorine-based material included in the precursor reacts with arsenic precursor. (As), arsenic (As) may be lost in silicon oxide.

Loss of the first and second dopants 521 and 523, for example, arsenic (As), may start from the sidewalls of the first and second selector layers P1 and P2 that contact the spacer 540, and may progress toward the centers of the first and second selector layers P1 and P2 in a horizontal direction. Accordingly, edges corresponding to a predetermined width from the sidewalls of the first and second selector layers P1 and P2 may become a dead region DR where the first and second dopants 521 and 523 are lost. Since the dead region DR does not have trap sites to the extent of enabling the movement of conductive carriers due to the loss of the first and second dopants 521 and 523, it may not have threshold switching characteristics and may have insulating characteristics. At least a portion of the dead region DR may include a combination of a chlorine-based element and arsenic (As). Since the loss of the first and second dopants 521 and 523 starts from the sidewalls of the first and second selector layers P1 and P2, the width of the dead region DR may be substantially constant regardless of its height.

On the other hand, remaining portions, except for the edges of the first and second selector layers P1 and P2, that is, the centers where their sidewalls are surrounded by the edges, may correspond to an active region AR where the first and second dopants 521 and 523 are maintained. Since there is no loss of the first and second dopants 521 and 523 in the active region AR, threshold switching characteristics may be maintained.

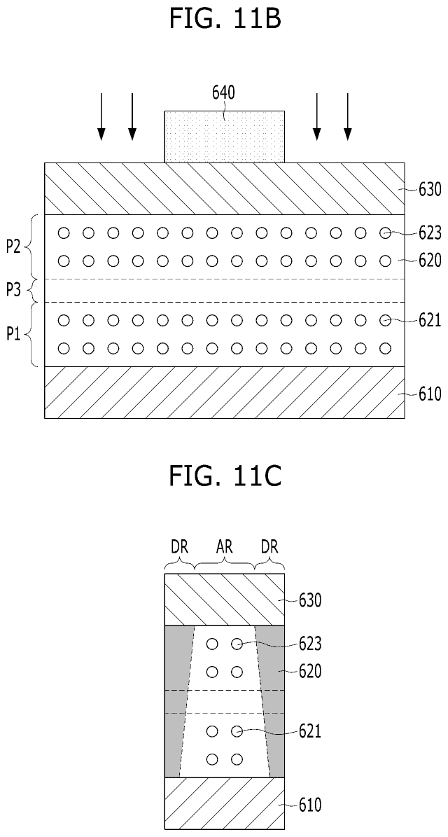

FIGS. 11A to 11C are cross-sectional views illustrating another example of a method of forming the memory cell of FIG. 9.

Referring to FIG. 11A , substantially the same processes as FIGS. 8A to 8D may be performed to form a stacked structure including a conductive layer 610, a first selector layer P1 in which a first dopant 621 is doped in an insulating material layer 620, a second selector layer P2 in which a second dopant 623 is doped in the insulating material layer 620, and a portion P3 located between the first selector layer P1 and the second selector layer P2 and including the insulating material layer 620 not doped with a dopant, and a second conductive layer 630. This stacked structure may be in a state before being patterned, and may need to be patterned into a pillar shape in a subsequent process.

Referring to FIG. 11B, a mask pattern 640 may be formed over the stacked structure of FIG. 11A to pattern the stacked structure into a pillar shape.

Subsequently, the stacked structure of FIG. 11A may be etched using the mask pattern 640 as an etch barrier. This etching process may be performed by anisotropic etching, for example, dry etching, in the direction of the arrow. Also, during the etching process, an etching gas containing an element capable of removing the first and second dopants 621 and 623 by reacting with the first and second dopants 621 and 623 may be used.

As an example, when the first and second dopants 621 and 623 include arsenic (As), a chlorine-based etching gas may be used. As a chlorine-based material included in the etching gas reacts with arsenic (As), arsenic (As) may be lost in silicon oxide.

During the etching process, loss of the first and second dopants 621 and 623 may start from a side surface formed by etching the first and second selector layers P1 and P2.

That is, the exposure time to the etching gas may increase from top to bottom of the side surface. The result of the etching process is shown in FIG. 11C.

Referring to FIG. 11C, edges corresponding to a predetermined width from sidewalls of the first and second selector layers P1 and P2 may be dead regions DR where the first and second dopants 621 and 623 are lost. Remaining portions, except for the edges of the first and second selector layers P1 and P2, that is, the centers where their sidewalls are surrounded by the edges, may correspond to an active region AR where the first and second dopants 621 and 623 are maintained.

Here, as described above, since the time exposed to the etching gas increases from the top to the bottom of the side surfaces of the selector layers P1 and P2, the width of the dead region DR may decrease from top to bottom.

Accordingly, the disclosed technology can be implemented in some embodiments to provide a highly integrated semiconductor device having excellent operating characteristics and. In addition, the disclosed technology can be implemented in some embodiments to provide a method for fabricating the semiconductor device.

Only a few embodiments and examples are described. Enhancements and variations of the disclosed embodiments and other embodiments can be made based on what is described and illustrated in this patent document.

What is claimed is:

1. A semiconductor device comprising:
first and second conductive layers spaced apart from each other; and
a memory cell interposed between the first and second conductive layers,
wherein the memory cell includes:
a first selector layer;
a second selector layer spaced apart from the first selector layer; and
an insulating layer interposed between the first selector layer and the second selector layer.

2. The semiconductor device according to claim 1, wherein the first selector layer is turned on at or above a first sub-threshold voltage,
the second selector layer is turned on at or above a second sub-threshold voltage, and
a soft breakdown of the insulating layer occurs at or above a breakdown voltage.

3. The semiconductor device according to claim 1, wherein a thickness of the insulating layer is smaller than a thickness of the first selector layer and a thickness of the second selector layer.

4. The semiconductor device according to claim 1, wherein a thickness of the insulating layer has a range of several to several tens of nm.

5. The semiconductor device according to claim 1, wherein a thickness of the first selector layer has a range of 90% to 110% of a thickness of the second selector layer.

6. The semiconductor device according to claim 1, wherein the first selector layer includes a first insulating material layer and a first dopant doped in the first insulating material layer to create a shallow trap providing a passage for a conductive carrier to move, and
the second selector layer includes a second insulating material layer and a second dopant doped in the second insulating material layer to create a shallow trap providing a passage for a conductive carrier to move.

7. The semiconductor device according to claim 6, wherein the first insulating material layer, the second insulating material layer, and the insulating layer include a same insulating material.

8. The semiconductor device according to claim 1, wherein each of the first and second selector layers includes a dead region corresponding to an edge from a sidewall of each of the first and second selector layers and not functioning as a selector, and an active region having a sidewall surrounded by the dead region and functioning as a selector.

9. The semiconductor device according to claim 8, wherein the active region of the first selector layer includes a first insulating material layer and a first dopant having a first concentration doped into the first insulating material layer to create a shallow trap providing a passage for a conductive carrier to move,
the dead region of the first selector layer includes the first insulating material layer and the first dopant having a second concentration equal to or greater than 0 and lower than the first concentration,
the active region of the second selector layer includes a second insulating material layer and a second dopant having a third concentration doped into the second insulating material layer to create a shallow trap providing a passage for a conductive carrier to move, and
the dead region of the second selector layer includes the second insulating material layer and the second dopant having a fourth concentration equal to or greater than 0 and lower than the third concentration.

10. The semiconductor device according to claim 9, wherein the first and second dopants include arsenic, and the dead region includes a combination of a chlorine-based element and arsenic.

11. The semiconductor device according to claim 8, wherein the dead region has a width that decreases from top to bottom.

12. The semiconductor device according to claim 2, wherein a first threshold voltage is a sum of the first sub-threshold voltage, the second sub-threshold voltage, and the breakdown voltage, wherein a conductive path is formed in each of the first selector layer, the insulating layer, and the second selector layer during a write operation, wherein a write voltage applied during the write operation has a magnitude greater than the first threshold voltage.

13. The semiconductor device according to claim 12, wherein a second threshold voltage is a sum of the first sub-threshold voltage and the second sub-threshold voltage, wherein, during an erase operation, a conductive path is formed in each of the first selector layer and the second selector layer, and a conductive path previously formed in the insulating layer disappears, wherein an erase voltage applied during the erase operation has a magnitude greater than the second threshold voltage and less than the first threshold voltage.

14. The semiconductor device according to claim 13, wherein a polarity of the write voltage is the same as a polarity of the erase voltage.

15. The semiconductor device according to claim 13, wherein a read voltage applied during a read operation for reading a resistance state of the memory cell has a magnitude greater than the second threshold voltage and less than the erase voltage.

16. The semiconductor device according to claim 15, wherein a polarity of the read voltage is the same as a polarity of the write voltage and a polarity of the erase voltage.

17. The semiconductor device according to claim 13, wherein the conductive path of the insulating layer disappears by Joule's heat generated according to the erase voltage.

18. The semiconductor device according to claim 13, wherein at least part of the conductive path of the insulating layer disappears.

19. The semiconductor device according to claim 13, wherein the conductive path of the insulating layer remains even after power is removed, until the erase voltage is applied. 20 A method for fabricating a semiconductor device, comprising:
forming an insulating material layer between a first conductive layer and a second conductive layer;
forming a first selector layer arranged adjacent to the first conductive layer by doping a first dopant into a lower portion of the insulating material layer adjacent to the first conductive layer; and
forming a second selector layer arranged adjacent to the second conductive layer by doping a second dopant into an upper portion of the insulating material layer adjacent to the second conductive layer,
wherein a portion of the insulating material layer between the first selector layer and the second selector layer is not doped with the first and second dopants.

21. The method according to claim 20, wherein the doping of the first dopant is performed by ion implantation, and
a target depth of the ion implantation is located in the first selector layer.

22. The method according to claim 20, wherein the doping of the second dopant is performed by ion implantation, and
a target depth of the ion implantation is located in the second selector layer.

23. The method according to claim 20, wherein the doping of the first and second dopants is performed so that a thickness of the remaining portion of the insulating material layer is smaller than a thickness of the first selector layer and a thickness of the second selector layer.

24. The method according to claim 20, wherein the doping of the first and second dopants is performed so that a thickness of the remaining portion of the insulating material layer has a range of several to several tens of nm.

25. The method according to claim 20, wherein the doping of the first and second dopants is performed so that a thickness of the first selector layer has a range of 90% to 110% of a thickness of the second selector layer.

26. The method according to claim 20, further comprising:
patterning a stacked structure of the first selector layer, the portion of the insulating material layer, and the second selector layer, after the forming of the second selector layer; and
forming a spacer over a sidewall of the patterned stacked structure,
wherein the forming of the spacer is performed using a precursor including an element that reacts with the first and second dopants to cause loss of the first and second dopants.

27. The method according to claim 26, wherein the first and second dopants include arsenic, and the element includes a chlorine-based element.

28. The method according to claim 20, further comprising:
forming a mask pattern over the second selector layer, after the forming of the second selector layer; and
etching the first selector layer, the portion of the insulating material layer, and the second selector layer, using the mask pattern as an etch barrier,
wherein the etching is performed using an etching gas containing an element that reacts with the first and second dopants to cause loss of the first and second dopants.

29. The method according to claim 28. wherein the first and second dopants include arsenic, and the element includes a chlorine-based element.
